(19) United States
(12) Patent Application Publication
(10) Pub. No.: US 2025/0169383 A1
(43) Pub. Date: May 22, 2025

(54) VERTICAL TERNARY CMOS INVERTER USING 2D MATERIAL AND METHOD OF MANUFACTURING THE SAME

(71) Applicant: UIF (University Industry Foundation), Yonsei University, Seoul (KR)

(72) Inventors: Jiwon Chang, Seoul (KR); Sekwon Hong, Seoul (KR); Changwook Lee, Seoul (KR); Jae Eun Seo, Hwaseong-si, Gyeonggi-do (KR)

(21) Appl. No.: 18/953,095

(22) Filed: Nov. 20, 2024

(30) Foreign Application Priority Data
Nov. 21, 2023 (KR) 10-2023-0161867
Nov. 14, 2024 (KR) 10-2024-0162056

(51) Int. Cl. H10N 70/20; H10D 30/01; H10D 30/47; H10D 62/13; H10D 62/17; H10D 64/23; H10D 64/27

(52) U.S. Cl. CPC H10N 70/231; H10D 30/027; H10D 30/481; H10D 62/154; H10D 62/155; H10D 62/158; H10D 62/235; H10D 64/251; H10D 64/512

(57) ABSTRACT

A CMOS element includes an n-MOSFET and a p-MOSFET that share a common gate and a common drain. An n-type channel layer of the n-MOSFET is stacked so as to be located in a lower area with respect to the common gate, a p-type channel layer of the p-MOSFET is stacked so as to be located in an upper area with respect to the common gate, and the common drain is stacked so as to be located in a lateral area with respect to the common gate.

### CROSS-REFERENCE TO RELATED APPLICATIONS

This application claims priority under 35 U.S.C. § 119 to Korean Patent Application No. 10-2023-0161867 filed on Nov. 21, 2023 and Korean Patent Application No. 10-2024-0162056 filed on Nov. 14, 2024, in the Korean Intellectual Property Office, the disclosures of which are incorporated by reference herein in their entireties.

### BACKGROUND

Embodiments of the present disclosure described herein relate to a CMOS element for enabling ternary operations.

The present disclosure is derived from the research conducted as part of the personal basic research (Project Identification Number: 1711181765, Project Number: 2022R1A2C2008726, Research Project Title: Research on Monolithic 3D Integrable Ternary CMOS Technology Using Phase Transition Depending on Thickness of 2D Material for Implementation of Logic-in-Memory, Project Management Organization: National Research Foundation of Korea, Project Executing Organization: Yonsei University, Research Period: 2023.03.01˜ 2024.02.29) of the Ministry of Science and ICT. Meanwhile, the Korean government has no property interest in all aspects of the present disclosure.

A complementary metal-oxide semiconductor (CMOS), which is a type of integrated circuit, is widely used in circuits of most electronic devices. The CMOS is an element having a MOSFET (p-MOS) of a p channel and a MOSFET (n-MOS) of an n channel formed in a single chip and allows the MOS of the p channel and the MOS of the n channel to complementarily operate. The CMOS is mainly used to constitute an integrated circuit such as a microprocessor, a static random access memory (SRAM), an image sensor, or the like. The CMOS is widely used because it is cheaper than a process using a BJT element and is capable of implementing a low-power circuit.

Recently, studies on semiconductor device technology have been widely conducted to address the problem of how much power consumption can be reduced. However, there is a problem that it is difficult to fundamentally solve the power consumption problem in processing of large amounts of information, such as big data, using a binary element that expresses information in the binary system of 0 and 1.

### SUMMARY

Embodiments of the present disclosure provide a ternary CMOS element for performing ternary operations.

Furthermore, embodiments of the present disclosure provide a 2D material-based ternary CMOS element for supporting a wide range of operating speeds so as to be used for various purposes from an ultra-low power environment to a high performance environment.

Moreover, embodiments of the present disclosure provide a ternary CMOS element for more robustly and stably implementing a constant current without a problem of process dispersion due to doping.

In addition, embodiments of the present disclosure provide a ternary CMOS element for increasing the degree of integration of an element using a semiconductor material capable of an upper integration process under a process condition that does not deteriorate Si-based CMOS characteristics and reliability.

Meanwhile, the technical problems to be solved by the present disclosure are not limited to the aforementioned problems, and any other technical problems not mentioned herein will be clearly understood from the following description by those skilled in the art to which the present disclosure pertains.

According to an embodiment, a CMOS element includes an n-MOSFET and a p-MOSFET that share a common gate and a common drain. An n-type channel layer of the n-MOSFET is stacked so as to be located in a lower area with respect to the common gate, a p-type channel layer of the p-MOSFET is stacked so as to be located in an upper area with respect to the common gate, and the common drain is stacked so as to be located in a lateral area with respect to the common gate. The CMOS element further includes a first 2D phase change layer that is composed of a first 2D phase change material located in a first area between the common drain and the n-type channel layer and that has one end connected to the n-type channel layer and an opposite end connected to a lower end of the common drain and a second 2D phase change layer that is composed of a second 2D phase change material located in a second area between the common drain and the p-type channel layer and that has one end connected to the p-type channel layer and an opposite end connected to an upper end of the common drain.

The n-type channel layer of the n-MOSFET and the p-type channel layer of the p-MOSFET may be stacked in opposite areas that face each other with respect to the common gate. The first 2D phase change layer including the first 2D phase change material may be provided in the first area between the common drain and the n-type channel layer, and the second 2D phase change layer including the second 2D phase change material may be provided in the second area between the common drain and the p-type channel layer.

At least one of the first 2D phase change material or the second 2D phase change material may be composed of a 2D phase change material having a decreasing band gap depending on an increase in a thickness of a layer.

At least one of the first 2D phase change material or the second 2D phase change material may be composed of at least one of platinum diselenide (PtSe₂), palladium diselenide (PdSe₂), arsenene being an allotrope material of arsenic (As), or antimonene being an allotrope of antimony (Sb).

At least one of the n-type channel layer or the p-type channel layer may be composed of at least one of MoS₂ or WSe₂.

The first 2D phase change layer, the second 2D phase change layer, and the common drain may be formed on the same plane, and a connection metal may be provided in the second area.

The first 2D phase change layer and the second 2D phase change layer may be stacked in opposite areas that face each other with respect to the common drain.

At least one of the first 2D phase change layer or the second 2D phase change layer may be configured such that a constant current flows between the common gate and the common drain.

The CMOS element may further include a first oxide material layer stacked between the common gate and the n-type channel layer and a second oxide material layer stacked between the common gate and the p-type channel layer.

The n-MOSFET may be composed of a first source, the n-type channel layer, a first oxide material layer, the common drain, the common gate, and the first 2D phase change material. The p-MOSFET may be composed of a second source, the p-type channel layer, a second oxide material layer, the common drain, the common gate, and the second 2D phase change material. The first area may be located at an end of the n-type channel layer of the n-MOSFET, and the first 2D phase change layer may be provided in the first area. The second area may be located at an end of the p-type channel layer of the p-MOSFET, and the second 2D phase change layer may be provided in the second area. The first area and the second area may be provided above and below the common drain, respectively.

The n-MOSFET may be composed of a first source, the n-type channel layer, a first oxide material layer, the common drain, the common gate, and the first 2D phase change material. The p-MOSFET may be composed of a second source, the p-type channel layer, a second oxide material layer, the common drain, the common gate, and the second 2D phase change material. The first area may be located at an end of the n-type channel layer of the n-MOSFET, and the first 2D phase change layer may be provided in the first area. A connection metal may be provided between an end of the p-type channel layer of the p-MOSFET and the second area, and the first area and the second area may be located on the same plane.

According to an embodiment, a CMOS element includes an n-MOSFET and a p-MOSFET that share a common gate and a common drain. An n-type channel layer of the n-MOSFET is stacked so as to be located in a lower area with respect to the common gate, a p-type channel layer of the p-MOSFET is stacked so as to be located in an upper area with respect to the common gate, and the common drain is stacked so as to be located in a lateral area with respect to the n-type channel layer. The CMOS element further includes a first 2D phase change layer that is composed of a first 2D phase change material located in a first area between the common drain and the n-type channel layer and that has one end connected to the n-type channel layer and an opposite end connected to one end of the common drain, a connection metal connected at one end thereof to one end of the p-type channel layer and electrically connected with the p-type channel layer, and a second 2D phase change layer that is composed of a second 2D phase change material located in a second area between the common drain and an opposite end of the connection metal and that has one end connected to an opposite end of the common drain and an opposite end connected to the opposite end of the connection metal.

The p-type channel layer may be connected at the one end thereof to the one end of the connection metal and may be connected at an opposite end thereof to a first source.

The n-MOSFET may be composed of the first source, the n-type channel layer, a first oxide material layer, the common drain, the common gate, and the first 2D phase change material. The p-MOSFET may be composed of a second source, the p-type channel layer, a second oxide material layer, the common drain, the common gate, and the second 2D phase change material. The first area may be located at an end of the n-type channel layer of the n-MOSFET, and the first 2D phase change layer may be provided in the first area. The connection metal may be provided between the one end of the p-type channel layer of the p-MOSFET and the second area and may electrically connect the p-type channel layer of the p-MOSFET and the second 2D phase change layer. The first area and the second area may be located on the same plane.

Positions where the n-MOSFET and the p-MOSFET are provided, respectively, may be changed.

According to an embodiment, a CMOS element manufacturing method includes a step of forming the n-MOSFET and the p-MOSFET that share the common gate and the common drain and a step of forming the first 2D phase change layer and the second 2D phase change layer between the n-MOSFET and the p-MOSFET. The step of forming the n-MOSFET and the p-MOSFET includes a step of stacking the n-type channel layer of the n-MOSFET and the p-type channel layer of the p-MOSFT in the opposite areas that face each other with respect to the common gate. The step of forming the first 2D phase change layer and the second 2D phase change layer includes a step of forming the first 2D phase change layer including the first 2D phase change material in the first area between the common drain and the n-type channel layer and a step of providing the second 2D phase change layer including the second 2D phase change material in the second area between the common drain and the p-type channel layer.

The first 2D phase change layer and the second 2D phase change layer may be formed so as not to be located on the same plane.

The first 2D phase change layer and the second 2D phase change layer may be formed on the same plane.

The ternary CMOS element according to the embodiments of the present disclosure may perform ternary operations.

Furthermore, the ternary CMOS element according to the embodiments of the present disclosure may support a wide range of operating speeds so as to be used for various purposes from an ultra-low power environment to a high performance environment.

Moreover, the ternary CMOS element according to the embodiments of the present disclosure may more robustly and stably implement a constant current without a problem of process distribution due to doping.

In addition, the ternary CMOS element according to the embodiments of the present disclosure may increase the degree of integration of an element using a semiconductor material capable of an upper integration process under a process condition that does not deteriorate Si-based CMOS characteristics and reliability.

Meanwhile, effects of the present disclosure are not limited to the aforementioned effects, and any other effects not mentioned herein will be clearly understood from the following description by those skilled in the art to which the present disclosure pertains.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a ternary CMOS element in which a first area and a second area are not located on the same plane according to an embodiment;

FIG. 2 is a view illustrating a ternary CMOS element in which a first area and a second area are located on the same plane according to an embodiment;

FIG. 3 is a view illustrating 2D phase change materials;

FIG. 4 is a graph for explaining a 2D phase change material having a decreasing band gap depending on an increase in thickness;

FIG. 5 is a graph for explaining a 2D phase change material having an increasing conductivity depending on an increase in thickness;

FIG. 6 is a view for explaining three states implemented in a ternary inverter;

FIG. 7 is a view for explaining a ternary element whose circuit complexity depending on an increase in logic radix is decreased when compared to that in the related art;

FIG. 8 is a view for explaining a possibility of simplification of artificial neural network connection by introduction of a ternary element;

FIG. 9 is a circuit diagram illustrating characteristics of a ternary CMOS element according to an embodiment;

FIG. 10 is a graph depicting a current flowing in the ternary CMOS element depending on a voltage applied to a gate; and

FIG. 11 is a graph depicting input/output characteristics of the ternary CMOS element according to an embodiment.

### DETAILED DESCRIPTION

Hereinafter, embodiments of the present disclosure will be described in detail with reference to the accompanying drawings such that those skilled in the art to which the present disclosure pertains can readily carry out the present disclosure. However, the present disclosure may be implemented in various different forms and is not limited to the embodiments described herein.

In the drawings, parts irrelevant to the description are omitted for the simplicity of explanation, and throughout the specification, the same or similar components are assigned with the same reference numerals if possible. Accordingly, the reference numerals described above may also be used in other drawings.

The sizes and thicknesses of components illustrated in the drawings are arbitrarily illustrated for convenience of description, and therefore the present disclosure is not necessarily limited to those illustrated in the drawings. The thicknesses of layers and areas may be exaggerated for clarity in the drawings.

The expression “the same” in the description may mean “substantially the same”. That is, it may mean the sameness that can be understood by those skilled in the art. Other expressions may also be expressions from which “substantially” is omitted.

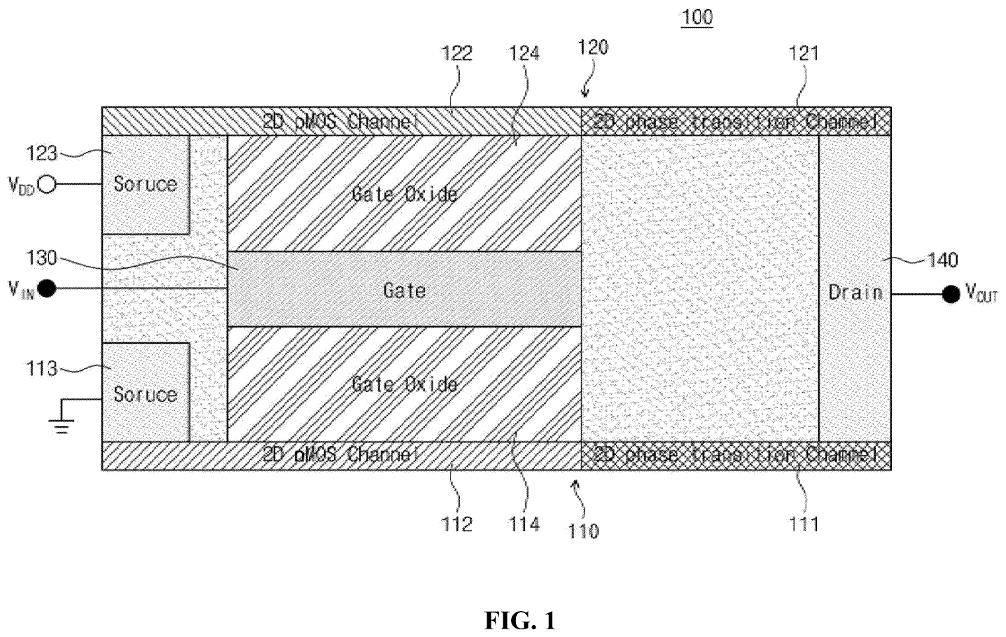

FIG. 1 is a view illustrating a ternary CMOS element in which a first area and a second area are not located on the same plane according to an embodiment.

Referring to FIG. 1, the ternary CMOS element 100 may include two MOSFET areas 110 and 120 and a common gate 130. The ternary CMOS element 100 may be a CMOS element capable of performing ternary operations, unlike a conventional CMOS element that generally performs binary operations. The common gate 130 may have an input voltage applied thereto. Each of the MOSFET areas may include a 2D phase change material layer, a 2D semiconductor material layer, a common drain 140, a source, and a first oxide material layer 114.

The 2D phase change material layer may serve to generate a constant current in an intermediate state by limiting a current applied to each of the n-MOSFET 110 and the p-MOSFET 120 to a predetermined level.

The 2D phase change material layer may be composed of a 2D phase change material. The 2D phase change material layer may be configured such that a constant current flows between the common drain 140 and the source irrespective of the magnitude of the input voltage VIN applied to the common gate 130.

The 2D semiconductor material layer may be composed of a 2D semiconductor material having a characteristic that it changes into a conductor by a voltage change without separate doping. The 2D semiconductor material layer may be stacked at an upper end or a lower end of the 2D phase change material layer. The 2D semiconductor material layer may be composed of a 2D semiconductor material having a characteristic that it changes into a conductor by a voltage change without separate doping. The 2D semiconductor material may be transition metal dichalcogenides (TMDCs) and may have a structure consisting of one transition metal element and two chalcogen elements. The 2D semiconductor material may have a layered structure and may mean a single layer or multiple layers of a crystalline material made of an atomic layer. The 2D semiconductor material may have the characteristics of a non-conductor at ordinary time. However, when an electric field is applied, the 2D semiconductor material may exhibit a characteristic that it changes into a conductor. That is, the 2D semiconductor material may be a material that exhibits a specific polarity only by a voltage change without separate doping.

The common drain 140 may be connected to one end of the first 2D phase change material layer and one end of the second 2D phase change material layer.

The first oxide material layer 114 may be stacked between the common gate 130 and an n-type channel layer 112 so as to be located between the common gate 130 and the n-type channel layer 112.

A first 2D phase change layer 111 and a second 2D phase change layer 121 may face each other with respect to the common drain 140. In addition, the first 2D phase change layer 111 and the second 2D phase change layer 121 may not be located on the same plane.

Specifically, the n-type channel layer 112 of the n-MOSFET 110 may be stacked so as to be located in a lower area with respect to the common gate 130.

A p-type channel layer 122 of the p-MOSFET 120 may be stacked so as to be located in an upper area with respect to the common gate 130.

The common drain 140 may be stacked so as to be located in a lateral area with respect to the common gate 130.

The first 2D phase change layer 111 may be composed of a first 2D phase change material located in the first area between the common drain 140 and the n-type channel layer 112. The first 2D phase change layer 111 may be connected at one end thereof to the n-type channel layer 112 and may be connected at an opposite end thereof to a lower end of the common drain 140.

The second 2D phase change layer 121 may be composed of a second 2D phase change material located in the second area between the common drain 140 and the p-type channel layer 122. The second 2D phase change layer 121 may be connected at one end thereof to the p-type channel layer 122 and may be connected at an opposite end thereof to an upper end of the common drain 140.

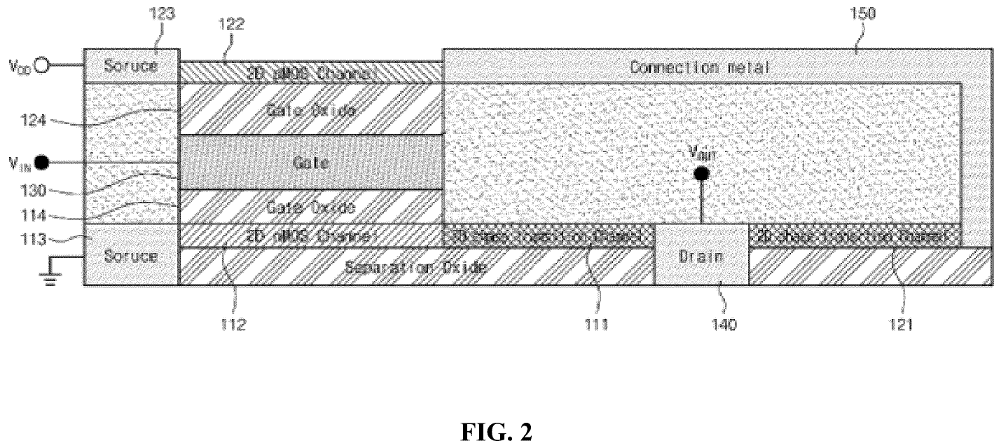

FIG. 2 is a view illustrating a ternary CMOS element in which a first area and a second area are located on the same plane according to an embodiment.

Referring to FIG. 2, each MOSFET area may further include a second oxide material layer 124.

The second oxide material layer 124 may be stacked between a common gate 130 and a p-type channel layer 122 so as to be located between the common gate 130 and the p-type channel layer 122.

Referring to FIGS. 1 and 2, one of two MOSFET areas may be an n-MOSFET area 110, and the other one of the two MOSFET areas may be a p-type MOSFET area 120.

In this case, the n-MOSFET area 110 may be located at a lower end, and the p-MOSFET area 120 may be located at an upper end. However, in contrast, the n-MOSFET area 110 may be located at the upper end, and the p-MOSFET area 120 may be located at the lower end.

The n-MOSFET area 110 may include a first 2D phase change layer 111, an n-type channel layer 112, a first source 113, a first oxide material layer 114, and a common drain 140.

The n-type channel layer 112 may be a 2D semiconductor material layer composed of a 2D semiconductor material having a characteristic that it changes into an n-type conductor by a voltage change without separate doping.

The n-type channel layer 112 may be composed of MoS₂. However, the present disclosure is no limited thereto, and it is apparent that various materials capable of forming an n channel among 2D semiconductor materials are able to be used for the n-type channel layer 112.

The first 2D phase change layer 111 may be a 2D phase change material layer composed of a 2D phase change material stacked at an upper end or a lower end of the n-type channel layer 112.

The first source 113 may be a source connected to one end of the n-type channel layer 112. The first source 113 may be electrically connected to a ground.

The n-type channel layer 112 may be provided between the first source 113, the first 2D phase change layer 111, and the common drain 140.

The first 2D phase change layer 111 may be provided between the n-type channel layer 112 and the common drain 140. The first 2D phase change layer 111 may be configured such that a constant current flows between the common drain 140 and the first source 113 irrespective of the magnitude of a voltage applied to the common gate 130

The p-MOSFET area 120 may include a second 2D phase change layer 121, the p-type channel layer 122, a second source 123, the second oxide material layer 124, and the common drain 140.

The p-type channel layer 122 may be a 2D semiconductor material layer composed of a 2D semiconductor material having a characteristic that it changes into a p-type conductor by a voltage change without separate doping.

The p-type channel layer 122 may be composed of WSe₂. However, the present disclosure is no limited thereto, and it is apparent that various materials capable of forming a p channel among 2D semiconductor materials are able to be used for the p-type channel layer 122.

The second 2D phase change layer 121 may be a 2D phase change material layer composed of a 2D phase change material stacked at one end of the p-type channel layer 122 or at an opposite end of a connection metal 150.

The second source 123 may be connected to an opposite end of the p-type channel layer 122. The second source 123 may have a power supply voltage VDD applied thereto.

The p-type channel layer 122 may be provided between the second source 123, the second 2D phase change layer 121, the connection metal 150, and the common drain 140.

The second 2D phase change layer 121 may be provided between the p-type channel layer 122, the connection metal 150, and the common drain 140. The second 2D phase change layer 121 may be configured such that a constant current flows between the common drain 140 and the second source 123 irrespective of the magnitude of a voltage applied to the common gate 130.

Specifically, referring to FIG. 2, the n-type channel layer 112 of the n-MOSFET 110 may be stacked so as to be located in a lower area with respect to the common gate 130. The p-type channel layer 122 of the p-MOSFET 120 may be stacked so as to be located in an upper area with respect to the common gate 130.

The common drain 140 may be stacked so as to be located in a lateral area with respect to the n-type channel layer 112.

The first 2D phase change layer 111 may be composed of a first 2D phase change material located in the first area between the common drain 140 and the n-type channel layer 112. The first 2D phase change layer 111 may be connected at one end thereof to the n-type channel layer 112 and may be connected at an opposite end thereof to one end of the common drain 140.

The connection metal 150 may be connected at one end thereof to the one end of the p-type channel layer 122 and accordingly may be electrically connected with the p-type channel layer 122.

The second 2D phase change layer 121 may be composed of a second 2D phase change material located in the second area between the common drain 140 and the opposite end of the connection metal 150. The second 2D phase change layer 121 may be connected at one end thereof to an opposite end of the common drain 140 and may be connected at an opposite end thereof to the opposite end of the connection metal 150.

As illustrated, the connection metal 150 may be configured such that a portion connected to the p-type channel layer 122 is parallel to the ground and a portion connected to the second 2D phase change layer 121 is perpendicular to the ground. However, the connection metal 150 may have a different arrangement or shape as long as the connection electrode 150 is capable of electrically connecting the p-type channel layer 122 and the second 2D phase change layer 121.

The one end of the p-type channel layer 122 may be connected to the one end of the connection metal 150, and the opposite end of the p-type channel layer 122 may be connected to the second source 123.

The connection metal 150 may be provided between the one end of the p-type channel layer 122 of the p-MOSFET 120 and the second area and may electrically connect the p-type channel layer 122 of the p-MOSFET 120 and the second 2D phase change layer 121.

The common gate 130 may have an input voltage VIN applied thereto.

The common drain 140 may be connected to the opposite end of the first 2D phase change layer 111 and the one end of the second 2D phase change layer 121.

The n-MOSFET area 110 may be stacked at a lower end of the common gate 130, and the p-MOSFET area 120 may be stacked at an upper end of the common gate 130. However, the present disclosure is not limited thereto.

For example, in contrast, the n-MOSFET area 110 may be stacked at the upper end of the common gate 130, and the p-MOSFET area 120 may be stacked at the lower end of the common gate 130.

The common gate 130, the common drain 140, the first source 113, and the second source 123 may be formed by performing patterning through an Photolithography process and then depositing a metal through a deposition technique such as an E-beam evaporator.

The first oxide material layer 114 may be a first oxide material layer 114 stacked at the upper end of the n-type channel layer 112 and the lower end of the common gate 130 so as to be located between the n-type channel layer 112 and the common gate 130. The first oxide material layer 114 may serve to electrically insulate the n-type channel layer 112 and the common gate 130 from each other.

The n-type channel layer 112 may be stacked at the one end of the first 2D phase change layer 111.

The first oxide material layer 114 may be stacked at the upper end of the n-type channel layer 112.

The common gate 130 may be connected to an upper end of the first oxide material layer 114.

The second oxide material layer 124 may be a second oxide material layer stacked at a lower end of the p-type channel layer 122 and the upper end of the common gate 130 so as to be located between the p-type channel layer 122 and the common gate 130. The second oxide material layer 124 may serve to electrically insulate the p-type channel layer 122 and the common gate 130 from each other.

The p-channel 2D semiconductor material layer 122 may be stacked at a lower end of the p-channel side 2D phase change material layer 121.

The second oxide material layer 124 may be stacked at the lower end of the p-type channel layer 122.

The common gate 130 may be connected to a lower end of the second oxide material layer 124 and may be provided between the p-MOSFET area 120 and the n-MOSFET area 110.

The first oxide material layer 114 and the second oxide material layer 124 may be composed of a high-k material (e.g., Al₂O₃ or HfO₂).

The first oxide material layer 114 and the second oxide material layer 124 may be deposited through atomic layer deposition (ALD), but are not limited thereto.

A method of manufacturing the above-described ternary CMOS element 100 may include a step of depositing the n-type channel layer 112 at an upper end of the first 2D phase change layer 111.

The method of manufacturing the ternary CMOS element 100 may further include a step of depositing the first oxide material layer 114 at the upper end of the n-type channel layer 112.

The method of manufacturing the ternary CMOS element 100 may further include a step of connecting the common gate 130 to the upper end of the first oxide material layer 114.

The method of manufacturing the ternary CMOS element 100 may further include a step of depositing the second oxide material layer 124 at the upper end of the common gate 130.

The method of manufacturing the ternary CMOS element 100 may further include a step of depositing the p-type channel layer 122 at an upper end of the second oxide material layer 124.

Meanwhile, in the opposite case where the n-MOSFET area 110 is stacked at the upper end of the common gate 130 and the p-MOSFET area 120 is stacked at the lower end of the common gate 130, the stacking steps in the above-described method of manufacturing the ternary CMOS element 100 may be performed in the reverse order.

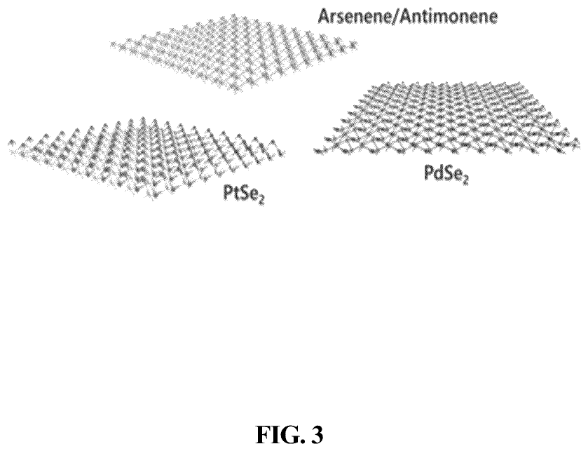

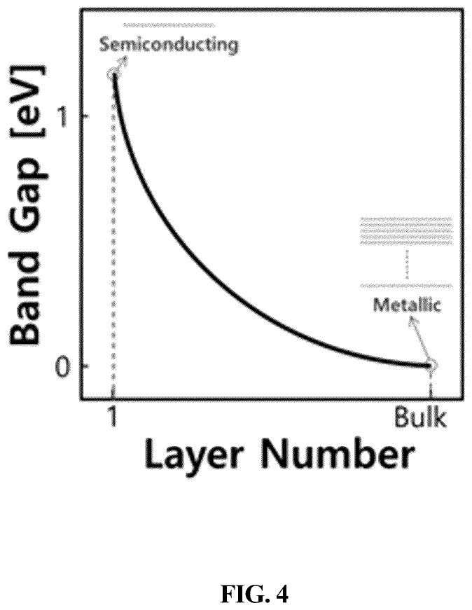

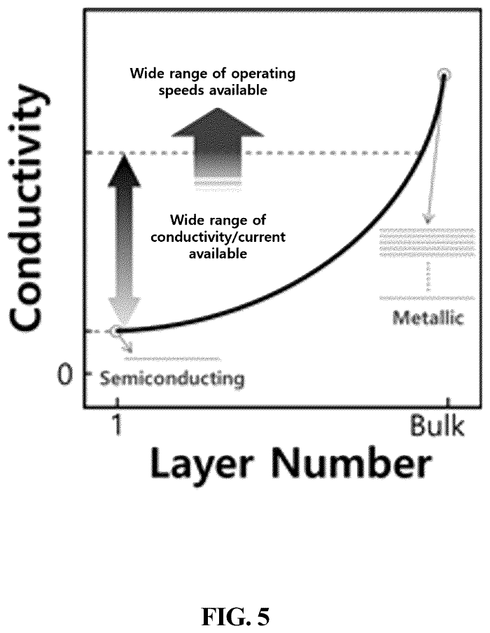

FIG. 3 is a view illustrating 2D phase change materials, FIG. 4 is a graph for explaining a 2D phase change material having a decreasing band gap depending on an increase in thickness, and FIG. 5 is a graph for explaining a 2D phase change material having an increasing conductivity depending on an increase in thickness.

Referring to FIGS. 3, 4, and 5, a 2D phase change material layer may be composed of a 2D phase change material having a characteristic that a band gap is reduced depending on an increase in the thickness of a layer.

The 2D phase change material layer, which is a 2D phase change channel, may be composed of a 2D material illustrated in FIG. 3 that exhibits phase transition from a semiconductor to a conductor depending on a change in thickness.

The 2D phase change material layer may be composed of transition metal dichalconenides (TMDs) having a characteristic that a band gap is reduced depending on an increase in the thickness of a layer. However, the 2D phase change material is not necessarily limited to the transition metal dichalconenides (TMDs).

The 2D phase change material layer may be composed of at least one of platinum diselenide (PtSe₂) or palladium diselenide (PdSe₂). However, the 2D phase change material is not limited to the above-described materials.

For example, the 2D phase change material layer may be composed of arsenene that is a 2D phase change material composed of a single element, in which the arsenene is an allotrope of arsenic (As) and has a 2D structure. Alternatively, the 2D phase change material layer may be composed of antimonene that is a 2D phase change material composed of a single element, in which the antimonene is an allotrope of antimony (Sb) and has a 2D structure.

As illustrated in FIG. 4, in the case of a monolayer, the 2D phase change materials, such as PdSe₂, PtSe₂, arsenene, and antimonene, may exhibit a phase transition phenomenon in which the 2D phase change materials have a band gap of 1 eV or more and accordingly have semiconducting characteristics but exhibit metallic characteristics due to a reduction of the band gap to zero depending on an increase in thickness.

When the above-described phase transition characteristics of the 2D phase change materials depending on the thickness change are used, a wide range of conductivity and current may be secured by adjusting the thickness as illustrated in FIG. 5. Accordingly, T-CMOS technology with a wide range of applications from ultra-low power to high performance may be implemented by supporting a wide range of operating speeds with the same element structure and process method.

In addition, since the 2D phase change materials are semiconductor materials that are able to be grown at low temperatures and subjected to upper integration processes under process conditions that do not deteriorate Si CMOS characteristics and reliability, the 2D phase change materials may be promising materials for monolithic 3D integration technology and may further improve the degree of integration of an element.

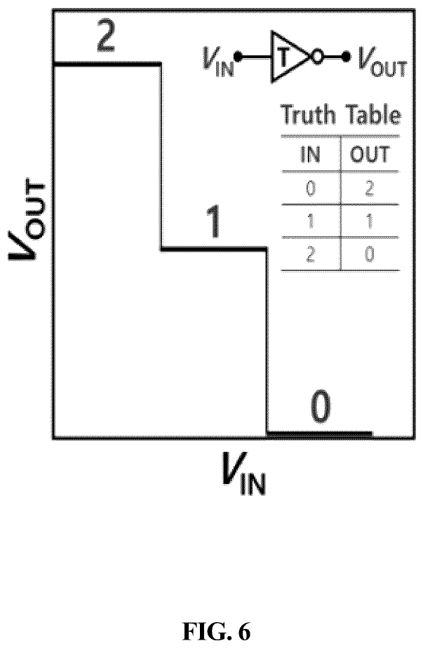

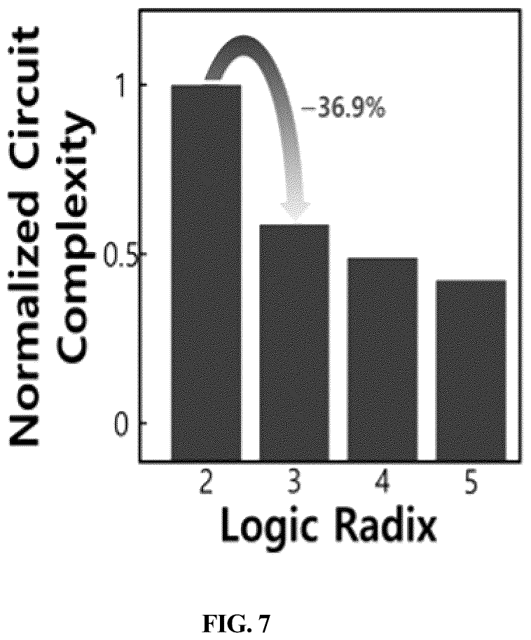

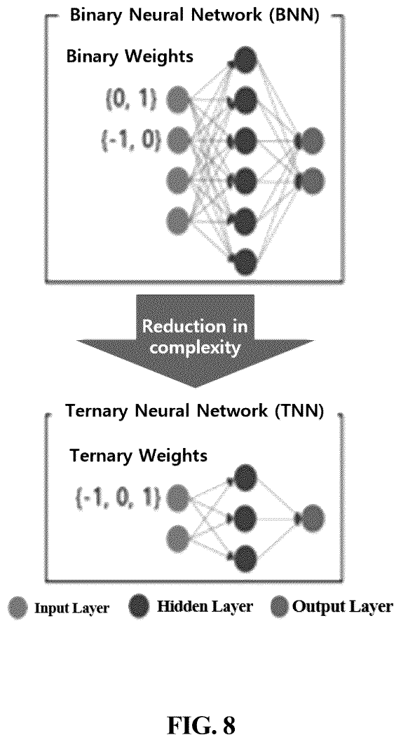

FIG. 6 is a view for explaining three states implemented in a ternary inverter, FIG. 7 is a view for explaining a ternary element whose circuit complexity depending on an increase in logic radix is decreased when compared to that in the related art, and FIG. 8 is a view for explaining a possibility of simplification of artificial neural network connection by introduction of a ternary element.

Referring to FIGS. 6, 7, and 8, it is possible to identify the advantages of an element using ternary operations compared to an element using conventional binary operations.

The ternary element illustrated in FIG. 6 may express information in the ternary system of 0, 1, and 2 to reduce the amount of information to be processed when compared to an existing binary element, thereby drastically improving a problem of power consumption.

When the representation of information is converted from the bit of the binary element to the trit of the ternary element, the voltage required for the state change in FIG. 6 may be half of that in the existing binary, and 2 bits may be expressed with 1 trit. Accordingly, the circuit complexity may be dramatically reduced as illustrated in FIG. 7, and thus power consumption may be drastically reduced. In addition, in the implementation of an artificial neural network, which has been actively studied in recent years, a reduction in power consumption may be achieved by simplifying the circuit connection by introducing ternary weights {-1, 0, 1} instead of the conventional binary weights {0, 1} as illustrated in FIG. 8.

In order to express information in the ternary system having the above-described advantages, the implementation of the ternary inverter (T-Inverter) of FIG. 6 is essential. In the related art, various studies have been actively conducted to form VDD/2 in an intermediate state by distributing a drive voltage VDD, but this method has many problems.

For example, a technology using stepped current-voltage characteristics by multiple threshold voltages in an element ON state by implementing multiple threshold voltages by resonant tunneling from a Si Channel to a QD by forming the quantum dot (QD) on gate oxide in a Si MOSFET has difficulty in implementing a stable constant current due to a threshold voltage distribution problem caused by non-uniform QD formation. This has a problem in that a constant current is formed in the element ON state so that static power consumption in an additional state is very large. In addition, it is difficult to reduce power consumption by operating voltage (VDD) scaling due to the implementation of the multiple threshold voltages.

A technology that uses negative differential resistance of an element ON state implemented at the level of a small flake obtained by a mechanical exfoliation technique by using negative differential resistance by tunneling in a 2D material heterostructure has a problem in that a constant current is formed in the element ON state so that static power consumption in an additional state is very large. In addition, there is a problem that it is difficult to reduce power consumption by operating voltage (VDD) scaling due to the implementation of multiple threshold voltages.

A technology using stepped current-voltage characteristics by multiple threshold voltages in an element ON state by implementing multiple threshold voltages based on the mobility edge quantization effect principle using a ZnO composite has a problem in that a constant current is formed in the element ON state so that static power consumption in an additional state is very large. In addition, there is a problem that it is difficult to reduce power consumption by operating voltage (VDD) scaling due to the implementation of the multiple threshold voltages.

A technology that uses a constant current in an element OFF state by implementing a small constant current component by tunneling independent of a gate voltage by forming a local PN junction at the bottom of a channel in a Si MOSFET uses the small constant current in the element OFF state and therefore has a problem in that the technology is only suitable for ultra-low power applications. Accordingly, it may be desirable to implement a CMOS element capable of ternary operations in a new way.

An existing ternary CMOS (T-CMOS) element has a clear limitation in an application range, whereas the illustrated ternary CMOS element 100 may support a wide range of operating speeds and may be used for various purposes from ultra-low power to high performance.

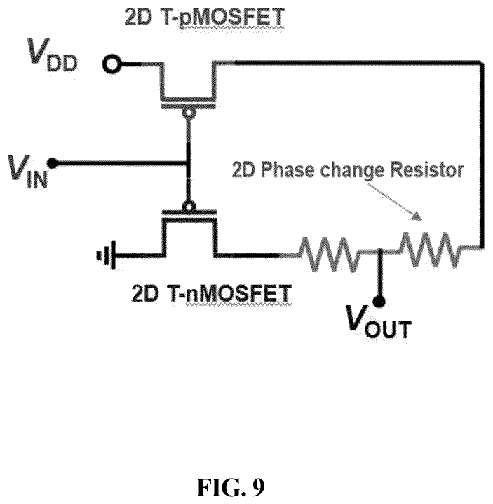

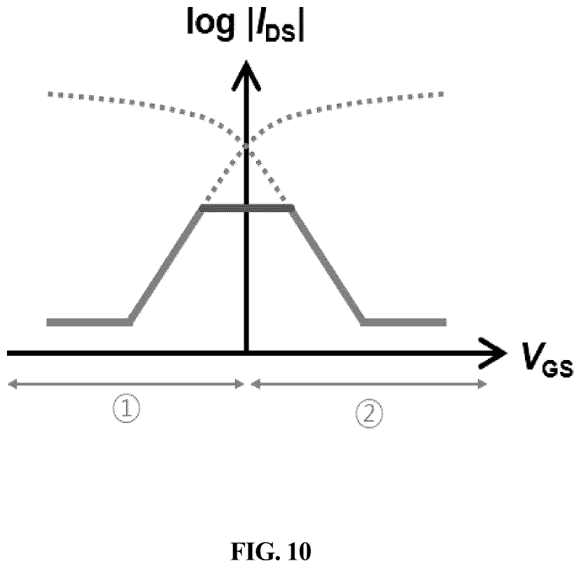

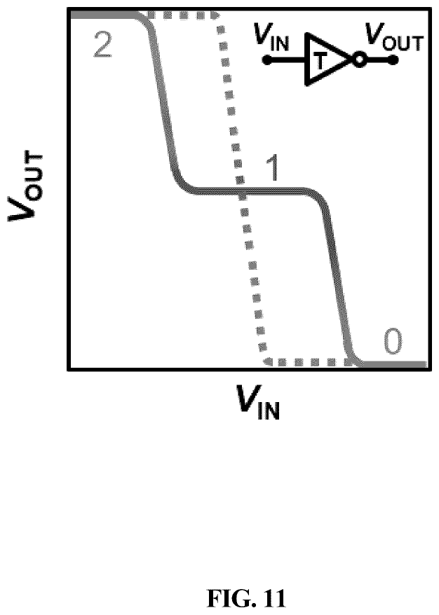

FIG. 9 is a circuit diagram illustrating characteristics of a ternary CMOS element according to an embodiment, FIG. 10 is a graph depicting a current flowing in the ternary CMOS element depending on a voltage applied to a gate, and FIG. 11 is a graph depicting input/output characteristics of the ternary CMOS element according to an embodiment.

Referring to FIGS. 9, 10, and 11, as can be seen from the illustrated I_{DS}-Vas characteristics, the 2D phase change material layer may generate a constant level of constant current in all operating ranges irrespective of the On/Off of the 2D n/p-MOSFETs, and when the 2D n/p-MOSFETs are all in an Off state, the influence of the 2D phase change material layer may be revealed, and as illustrated in FIG. 11, an intermediate state may be generated in the ternary CMOS element 100, that is, the T-CMOS Inverter.

The ternary CMOS element 100 may use a constant current in an element OFF state to implement an intermediate state of the ternary system. The used constant current may not be a current by Si-based junction tunneling, but may be a current flowing through the Schottky junction of source/drain metals and an undoped 2D material. The ternary CMOS element 100 according to an embodiment may more robustly and stably implement a constant current because there is no process distribution problem caused by doping.

Referring to the log|I_{DS}|−V_{GS} curve illustrated in FIG. 10, in the negative gate voltage range \textcircled{1}, the n-MOSFET 110 may start to turn on as the gate-source voltage V_{GS} increases, and the p-MOSFET may be in an ON state. In this case, as the gate-source voltage V_{GS} increases, the current may flow to the n-type channel layer 112, and the I_{DS} may increase at a specific point and may be saturated by the first 2D phase change layer 111.

In the positive gate voltage range \textcircled{2}, the p-MOSFET may start to turn on as the gate-source voltage V_{GS} decreases, and the n-MOSFET 110 may be in an ON state. In this case, as the gate-source voltage Vas decreases, the current may flow to the p-type channel layer 122, and the I_{DS} may increase at a specific point and may be saturated by the second 2D phase change layer 121.

Referring to FIG. 11, the input/output characteristics of the ternary CMOS element 100 according to an embodiment may be identified.

Since a constant current always flows through the 2D phase change material layer irrespective of the gate voltage, the constant current may generate a new intermediate state and may enable the function of the ternary CMOS element 100. Unlike previous T-CMOS studies using tunneling current, the ternary CMOS element 100 according to an embodiment may use the current through the Schottky junction of the source/drain metals and the undoped 2D material, which may lead to a constant current with high stability.

According to the embodiment of the present disclosure described above, the ternary CMOS element using the 2D phase change material capable of adjusting resistance and the manufacturing method thereof may provide a 2D material-based ternary CMOS inverter that is able to be used for various purposes from ultra-low power to high performance.

In addition, the ternary CMOS inverter element including the 2D phase change material in which the n-MOSFET 110, the p-MOSFET 120, the common gate 130, and the common drain 140 are vertically stacked and the manufacturing method thereof according to the present disclosure may improve the degree of integration through the vertical stacking.

The above description exemplifies the present disclosure. Furthermore, the above-mentioned contents describe embodiments of the present disclosure, and the present disclosure may be used in various other combinations, changes, and environments. That is, variations or modifications can be made to the present disclosure without departing from the spirit and scope of the present disclosure that is disclosed in the specification, the equivalent scope to the written disclosures, and/or the technical or knowledge range of those skilled in the art. The written embodiments describe the best state for implementing the technical spirit of the present disclosure, and various changes required in specific applications and purposes of the present disclosure can be made. Accordingly, the detailed description of the present disclosure is not intended to restrict the present disclosure in the disclosed embodiment state. In addition, it should be construed that the attached claims include other embodiments.

What is claimed is:

1. A CMOS element comprising:
an n-MOSFET and a p-MOSFET configured to share a common gate and a common drain,
wherein an n-type channel layer of the n-MOSFET is stacked so as to be located in a lower area with respect to the common gate,
wherein a p-type channel layer of the p-MOSFET is stacked so as to be located in an upper area with respect to the common gate,
wherein the common drain is stacked so as to be located in a lateral area with respect to the common gate, and
wherein the CMOS element further comprises:
a first 2D phase change layer composed of a first 2D phase change material located in a first area between the common drain and the n-type channel layer, the first 2D phase change layer having one end connected to the n-type channel layer and an opposite end connected to a lower end of the common drain; and
a second 2D phase change layer composed of a second 2D phase change material located in a second area between the common drain and the p-type channel layer, the second 2D phase change layer having one end connected to the p-type channel layer and an opposite end connected to an upper end of the common drain.

2. The CMOS element of claim 1, wherein at least one of the first 2D phase change material or the second 2D phase change material is composed of a 2D phase change material having a decreasing band gap depending on an increase in a thickness of a layer.

3. The CMOS element of claim 1, wherein at least one of the first 2D phase change material or the second 2D phase change material is composed of at least one of platinum diselenide (PtSe₂), palladium diselenide (PdSe₂), arsenene being an allotrope material of arsenic (As), or antimonene being an allotrope of antimony (Sb).

4. The CMOS element of claim 1, wherein at least one of the n-type channel layer or the p-type channel layer is composed of at least one of MoS₂ or WSe₂.

5. The CMOS element of claim 1, wherein the first 2D phase change layer, the second 2D phase change layer, and the common drain are formed on the same plane, and
wherein a connection metal is provided in the second area.

6. The CMOS element of claim 1, wherein the first 2D phase change layer and the second 2D phase change layer are stacked in opposite areas configured to face each other with respect to the common drain.

7. The CMOS element of claim 1, wherein at least one of the first 2D phase change layer or the second 2D phase change layer is configured such that a constant current flows between the common gate and the common drain.

8. The CMOS element of claim 1, further comprising:
a first oxide material layer stacked between the common gate and the n-type channel layer; and
a second oxide material layer stacked between the common gate and the p-type channel layer.

9. The CMOS element of claim 1, wherein the n-MOSFET is composed of a first source, the n-type channel layer, a first oxide material layer, the common drain, the common gate, and the first 2D phase change material,
wherein the p-MOSFET is composed of a second source, the p-type channel layer, a second oxide material layer, the common drain, the common gate, and the second 2D phase change material,
wherein the first area is located at an end of the n-type channel layer of the n-MOSFET, and the first 2D phase change layer is provided in the first area,
wherein the second area is located at an end of the p-type channel layer of the p-MOSFET, and the second 2D phase change layer is provided in the second area, and
wherein the first area and the second area are provided above and below the common drain, respectively.

10. A CMOS element comprising:
an n-MOSFET and a p-MOSFET configured to share a common gate and a common drain,
wherein an n-type channel layer of the n-MOSFET is stacked so as to be located in a lower area with respect to the common gate,
wherein a p-type channel layer of the p-MOSFET is stacked so as to be located in an upper area with respect to the common gate,
wherein the common drain is stacked so as to be located in a lateral area with respect to the n-type channel layer, and
wherein the CMOS element further comprises:
a first 2D phase change layer composed of a first 2D phase change material located in a first area between the common drain and the n-type channel layer, the first 2D phase change layer having one end connected to the n-type channel layer and an opposite end connected to one end of the common drain;
a connection metal connected at one end thereof to one end of the p-type channel layer and electrically connected with the p-type channel layer; and
a second 2D phase change layer composed of a second 2D phase change material located in a second area between the common drain and an opposite end of the connection metal, the second 2D phase change layer having one end connected to an opposite end of the common drain and an opposite end connected to the opposite end of the connection metal.

11. The CMOS element of claim 10, wherein the p-type channel layer is connected at the one end thereof to the one end of the connection metal and connected at an opposite end thereof to a first source,
wherein the n-MOSFET is composed of the first source, the n-type channel layer, a first oxide material layer, the common drain, the common gate, and the first 2D phase change material,
wherein the p-MOSFET is composed of a second source, the p-type channel layer, a second oxide material layer, the common drain, the common gate, and the second 2D phase change material,
wherein the first area is located at an end of the n-type channel layer of the n-MOSFET, and the first 2D phase change layer is provided in the first area,
wherein the connection metal is provided between the one end of the p-type channel layer of the p-MOSFET and the second area and electrically connects the p-type channel layer of the p-MOSFET and the second 2D phase change layer, and
wherein the first area and the second area are located on the same plane.

12. A CMOS element manufacturing method of manufacturing the CMOS element of claim 1, the CMOS element manufacturing method comprising:
a step of forming the n-MOSFET and the p-MOSFET configured to share the common gate and the common drain; and
a step of forming the first 2D phase change layer and the second 2D phase change layer between the n-MOSFET and the p-MOSFET,
wherein the step of forming the n-MOSFET and the p-MOSFET includes a step of stacking the n-type channel layer of the n-MOSFET and the p-type channel layer of the p-MOSFT in the opposite areas configured to face each other with respect to the common gate, and
wherein the step of forming the first 2D phase change layer and the second 2D phase change layer includes:
a step of forming the first 2D phase change layer including the first 2D phase change material in the first area between the common drain and the n-type channel layer; and
a step of providing the second 2D phase change layer including the second 2D phase change material in the second area between the common drain and the p-type channel layer.

13. The CMOS element manufacturing method of claim 12, wherein the first 2D phase change layer and the second 2D phase change layer are formed so as not to be located on the same plane.

14. The CMOS element manufacturing method of claim 12, wherein the first 2D phase change layer and the second 2D phase change layer are formed on the same plane.
